(19) United States
(12) Patent Application Publication
(10) Pub. No.: US 2024/0421076 A1
(43) Pub. Date: Dec. 19, 2024

(54) ADVANCED INTERCONNECTS WITH HYPERBOLOID PROFILE

(71) Applicant: INTERNATIONAL BUSINESS MACHINES CORPORATION, ARMONK, NY (US)

(72) Inventors: Oscar van der Straten, Guilderland Center, NY (US); Chih-Chao Yang, Glenmont, NY (US); Koichi Motoyama, Clifton Park, NY (US)

(21) Appl. No.: 18/333,642

(22) Filed: Jun. 13, 2023

(51) Int. Cl. H01L 23/528; H01L 21/768

(52) U.S. Cl. CPC H01L 23/528; H01L 21/76843; H01L 21/76877

(57) ABSTRACT

According to the embodiment of the present invention, a semiconductor device includes an interconnect. The interconnect includes a bottom interconnect section and a top interconnect section. The bottom interconnect section includes a first orientation along a Y-axis. The top interconnect section is coupled to the bottom interconnect section and includes a second orientation along to the Y-axis. The second orientation of the top interconnect section is a vertical reflection of the first orientation of the bottom interconnect section.

### BACKGROUND

The present invention relates generally to the field of microelectronics, and more particularly to a semiconductor device structure, and a method for forming a semiconductor device.

Higher device density—the ability to fit more electronic components onto a given area of a semiconductor device—is a key goal of each new generation of microelectronic fabrication. Increasing device density may lead to improved computing performance by integrating more functionality into a single chip. Device density may be increased by shrinking the minimum feature sizes of individual components (e.g., transistors, capacitors, resistors, interconnects) and the spacing (e.g., pitch) between adjacent components. However, as component dimensions continue to shrink, it has become more challenging to achieve a high degree of precision and uniformity during the fabrication process, leading to increased resistance, signal delays, and interference across the components of the resulting semiconductor devices.

### SUMMARY

According to an embodiment of the present invention, a semiconductor device includes an interconnect. The interconnect includes a bottom interconnect section and a top interconnect section. The bottom interconnect section includes a first orientation along a Y-axis. The top interconnect section is coupled to the bottom interconnect section and includes a second orientation along to the Y-axis. The second orientation of the top interconnect section is a vertical reflection of the first orientation of the bottom interconnect section.

According to an embodiment of the present invention, the bottom interconnect section includes a first interconnect portion and a second interconnect portion located above the first interconnect portion. The second interconnect portion includes a first wider region, a first narrower region located above the first wider region, and a first pair of tapered sidewalls that connects the first wider region and the first narrower region.

According to an embodiment of the present invention, the top interconnect section includes a third interconnect portion and a fourth interconnect portion. The third interconnect portion includes a second narrower region, a second wider region located above the second narrower region, and a second pair of tapered sidewalls that connects the second wider region and the second narrower region. The fourth interconnect portion is located above the second wider region of the third interconnect portion.

According to an embodiment of the present invention, the first pair of tapered sidewalls tapers up from the first wider region of the second interconnect portion towards a center line defined by the bottom interconnect section to define the first narrower region of the second interconnect portion. The second pair of tapered sidewalls tapers down from the second wider region of the third interconnect portion towards the center line to define the second narrower region of the third interconnect portion.

According to an embodiment of the present invention, the first pair of tapered sidewalls of the second interconnect portion and the second pair of tapered sidewalls of the third interconnect portion includes opposing orientations relative to each other along the Y-axis.

According to an embodiment of the present invention, an intersection is formed by the second narrower region of the third interconnect portion and the first narrower region of the second interconnect portion. The intersection joins the top interconnect section and the bottom interconnect section to form a continuous structure.

According to an embodiment of the present invention, the first interconnect portion extends a first width parallel to an X-axis. The first wider region of the second interconnect portion extends perpendicularly from the first interconnect portion on opposite sides of a center line defined by the bottom interconnect section to define a second width parallel to the X-axis. The first width is less than the second width.

According to an embodiment of the present invention, the second width of the first wider region tapers up to the first narrower region of the second interconnect portion. The first narrower region extends a third width parallel to the X-axis. The second width of the first wider region is greater than the third width of the first narrower region.

According to an embodiment of the present invention, the second wider region of the third interconnect portion extends a fourth width parallel to the X-axis and tapers down to the second narrower region of the third interconnect portion. The second narrower region extends a fifth width parallel to the X-axis. The fourth width is greater than the fifth width.

According to an embodiment of the present invention, the fourth width of the second wider region of the third interconnect portion and the second width of the first wider region of the second interconnect portion include a same width parallel to the X-axis.

According to an embodiment of the present invention, a semiconductor device includes an interconnect. The interconnect includes a first interconnect portion, a second interconnect portion, a third interconnect portion, and a fourth interconnect portion. The first interconnect portion extends along a Y-axis. The second interconnect portion extends upwards from the first interconnect portion along the Y-axis and includes a first tapered profile. The third interconnect portion extends upwards from the second interconnect portion along the Y-axis and includes a second tapered profile having an opposing orientation relative to the first tapered profile of the second interconnect portion. The fourth interconnect portion extends upwards from the third interconnect portion along the Y-axis.

According to an embodiment of the present invention, the first tapered profile of the second interconnect portion and the second tapered profile of the third interconnect portion forms a hyperboloid line profile along the Y-axis.

According to an embodiment of the present invention, the hyperboloid line profile includes a first locally widened critical dimension (CD) defined by a first wider region of the second interconnect portion and a second locally widened CD defined by a second wider region of the third interconnect portion. The first locally widened CD includes the opposing orientation relative to the second locally widened CD.

According to an embodiment of the present invention, the first interconnect portion is located between first sections of a first dielectric layer. The second interconnect portion and the third interconnect portion are located between second sections of a second dielectric layer. The fourth interconnect portion is located between third sections of a third dielectric layer.

According to an embodiment of the present invention, the first dielectric layer locating the first interconnect portion and the third dielectric layer locating the third interconnect portion includes different dielectric materials. The second dielectric layer includes a same dielectric material for the second interconnect portion and the third interconnect portion.

According to an embodiment of the present invention, a semiconductor device includes a first interconnect. The first interconnect includes a bottom interconnect section and a top interconnect section. The bottom interconnect section includes a first arrow-shaped profile extending along a Y-axis. The top interconnect section includes a second arrow-shaped profile extending along the Y-axis. The second arrow-shaped profile includes an opposite orientation relative to the first arrow-shaped profile.

According to an embodiment of the present invention, the bottom interconnect section includes a first interconnect portion and a second interconnect portion. The second interconnect portion includes a first arrowhead portion of the first arrow-shaped profile and the first interconnect portion includes a first shaft portion of the first arrow-shaped profile.

According to an embodiment of the present invention, the top interconnect section includes a third interconnect portion and a fourth interconnect portion. The third interconnect portion includes a second arrowhead portion of the second arrow-shaped profile and the fourth interconnect portion includes a second shaft portion of the second arrow-shaped profile.

According to an embodiment of the present invention, the first arrowhead portion of the first arrow-shaped profile and the second arrowhead portion of the second arrow-shaped profile forms a hyperboloid line profile along the Y-axis.

According to an embodiment of the present invention, the semiconductor device includes a second interconnect. The second interconnect and the first interconnect includes a uniform total interconnect height and a uniform line profile.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a cross-sectional view of an initial structure of a device after a first dielectric layer is formed on a base layer, in accordance with the embodiment of the present disclosure.

FIG. 2 illustrates a cross-sectional view of a partial structure of the device after a first hardmask layer is patterned on a top surface of the first dielectric layer, in accordance with the embodiment of the present disclosure.

FIG. 3 illustrates a cross-sectional view of the partial structure of the device after the first dielectric layer is selectively etched to create one or more trenches, in accordance with the embodiment of the present disclosure.

FIG. 4 illustrates a cross-sectional view of the partial structure of the device after the first hardmask layer is removed and a first barrier layer is deposited, in accordance with the embodiment of the present disclosure.

FIG. 5 illustrates a cross-sectional view of the partial structure of the device after a metallization process to form a first conductive material on the exposed surfaces, in accordance with the embodiment of the present disclosure.

FIG. 6 illustrates a cross-sectional view of the partial structure of the device after a second hardmask layer is patterned on a top surface of the first conductive material, in accordance with the embodiment of the present disclosure.

FIG. 7 illustrates a cross-sectional view of the partial structure of the device after the first conductive material and the first barrier layer is selectively etched, in accordance with the embodiment of the present disclosure the device.

FIG. 8 illustrates a cross-sectional view of the partial structure of the device after the second hardmask layer is removed and a second barrier layer is formed, in accordance with the embodiment of the present disclosure.

FIG. 9 illustrates a cross-sectional view of the partial structure of the device after regions of the second barrier layer are selectively removed, in accordance with the embodiment of the present disclosure.

FIG. 10 illustrates a cross-sectional view of the partial structure of the device after a second dielectric layer is formed, in accordance with the embodiment of the present disclosure.

FIG. 11 illustrates a cross-sectional view of the partial structure of the device after a third hardmask layer is patterned on a top surface of the second dielectric layer, in accordance with the embodiment of the present disclosure.

FIG. 12 illustrates a cross-sectional view of the partial structure of the device after the second dielectric layer is selectively etched, in accordance with the embodiment of the present disclosure.

FIG. 13 illustrates a cross-sectional view of the partial structure of the device after the third hardmask layer is removed and a third barrier layer is deposited, in accordance with the embodiment of the present disclosure.

FIG. 14 illustrates a cross-sectional view of the partial structure of the device after regions of the third barrier layer are selectively removed, in accordance with the embodiment of the present disclosure.

FIG. 15 illustrates a cross-sectional view of the partial structure of the device after a second conductive material is formed, in accordance with the embodiment of the present disclosure.

FIG. 16 illustrates a cross-sectional view of the partial structure of the device after a fourth hardmask layer is patterned on a top surface of the second conductive material, in accordance with the embodiment of the present disclosure.

FIG. 17 illustrates a cross-sectional view of the partial structure of the device after the second conductive material is selectively etched, in accordance with the embodiment of the present disclosure.

FIG. 18 illustrates a cross-sectional view of the partial structure of the device after a fourth barrier layer is formed and the fourth hardmask layer is removed, in accordance with the embodiment of the present disclosure.

FIG. 19 illustrates a cross-sectional view of a final structure of the device after a third dielectric layer is formed, in accordance with the embodiment of the present disclosure.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural references unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection.”

As used herein, the term “about” modifying the quantity of an ingredient, component, or reactant of the invention employed refers to variations in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various microelectronic fabrication processes which are used to form a micro-chip that will be packaged into an integrated circuit (IC) fall in four general categories, namely, film deposition, removal/etching, semiconductor doping, and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present disclosure, examples of which are illustrated in the accompanying drawings, where like reference numerals refer to like elements throughout.

Increasing device density is a critical goal of microelectronic fabrication, as it can lead to higher computing performance and lower costs per IC unit. Device density can be increased by reducing the dimensions of individual components (e.g., interconnects, transistors), as well as reducing the pitch (e.g., spacing) between the individual components.

With specific reference to the back-end-of-line (BEOL) stage of microelectronic fabrication, achieving higher device density poses several challenges. For example, reducing the dimensions of the interconnects may result in interconnects with smaller cross-sectional areas. The reduction in cross-sectional area may increase the resistance-capacitance product (RC) delay of the interconnect system, causing increased signal delay and power consumption.

Further, as the pitch between adjacent interconnects is reduced, the available space for trenches and vias decreases as well. This can lead to forming trenches and vias with higher aspect ratios (e.g., narrower width relative to the height). When metallization is performed in trenches and vias with high aspect ratios, it can become more difficult to maintain uniformity in the deposited metal, leading to voids in the metal gapfill, variations in the critical dimensions (CD) of adjacent interconnects, and line wiggling. Moreover, the metal fill materials may impart stress on the narrower dimensions of the trenches or vias, causing line wiggling and variations in the CD and heights of adjacent interconnects. These issues can have several negative effects, such as increased resistance and signal delay across the interconnect system.

Embodiments of the present disclosure provides an interconnect system which can achieve higher device density (e.g., dimensions below 30 nanometer pitch) without sacrificing uniformity. In other words, even at higher device densities, each of the interconnects may include a uniform profile, height, and CD relative to the other interconnects in the interconnect system. Throughout the present disclosure, the terms interconnect, line, and wire are used interchangeably to refer generally to electrically conductive features that electrically connect the transistors and other components generated during front-end-of-line (FEOL) processing.

Embodiments of the present disclosure provides an advanced interconnect system including a plurality of interconnects, where each interconnect may comprise a plurality of portions. In one embodiment, the plurality of portions of each interconnect may include a first interconnect portion and a second interconnect portion that forms a bottom interconnect section, and a third interconnect portion and a fourth interconnect portion that forms a top interconnect section. In other embodiments, each interconnect may include any number of suitable interconnect portions.

According to one embodiment, each of the plurality of portions of the interconnect includes low aspect ratio dimensions and is formed sequentially to build a final structure of interconnect. Thus, while the final structure of the interconnect may include a high aspect ratio, the forming of low aspect ratio interconnect portions in multiple, sequential stages to build the final interconnect may reduce the typical risks of line wiggling and metal gapfill errors associated with building entire high aspect ratio structures in a single stage.

According to one embodiment, each interconnect is surrounded by a plurality of dielectric layers stacked vertically along a height of the interconnect. The first interconnect portion is located between sections of a first dielectric layer and includes a first interconnect height that is approximately equal to a first dielectric layer height. The second and third interconnect portions are located between sections of a second dielectric layer and include a combined second and third interconnect height that is approximately equal to a second dielectric layer height. The fourth interconnect portion is located between sections of a third dielectric layer and includes a fourth interconnect height that is approximately equal to a third dielectric layer height. The first interconnect height, the combined second and third interconnect height, and the fourth interconnect height may comprise a total interconnect height that is approximately equal to a total dielectric layer height of the combined first, second, and third dielectric layers. Since the total interconnect height of each interconnect is approximately equal to the total dielectric layer height, the plurality of interconnects in the interconnect system may include a uniform height that is approximately equal to the total dielectric layer height.

According to one embodiment, each of the plurality of interconnects may include a uniform line profile having the following features: a lower interconnect portion having a substantially perpendicular line sidewall profile (e.g., first interconnect portion) located between sections of a lower dielectric layer (e.g., first dielectric layer), two opposing middle interconnect portions (e.g., second interconnect portion and third interconnect portion) located between sections of a middle dielectric layer (e.g., second dielectric layer), where the opposing middle interconnect portions comprise a hyperboloid line profile, and an upper interconnect portion having a substantially perpendicular line sidewall profile (e.g., fourth interconnect portion) located between sections of an upper dielectric layer (e.g., third dielectric layer). Each of the two opposing middle interconnect portions (e.g., second interconnect portion and third interconnect portion) includes respective tapered sidewalls that tapers towards a vertical center line at an angle (e.g., approximately ranging from 25 to 45 degrees). As a result of the tapered sidewalls, each of the two opposing middle interconnect portions includes respective regions with widened CD, which promotes lower line resistance in the interconnect. The uniform line profile across the plurality of interconnects is enabled by the sequential forming of low aspect ratio interconnect portions (e.g., the first, second, third, and fourth interconnect portions) to build the interconnect.

According to one embodiment, the lower dielectric layer (e.g., first dielectric layer) associated with the lower interconnect portion (e.g., first interconnect portion) and the upper dielectric layer (e.g., third dielectric layer) associated with the upper interconnect portion (e.g., fourth interconnect portion) comprises different low dielectric constant (low-k) materials. According to one embodiment, the middle dielectric layer (e.g., second dielectric layer) associated with the two opposing middle interconnect portions (e.g., second interconnect portion and third interconnect portion) comprises a single low-k dielectric material. According to one embodiment, each of the plurality of interconnect portions is associated with a respective barrier material that is different relative to the other interconnect portions.

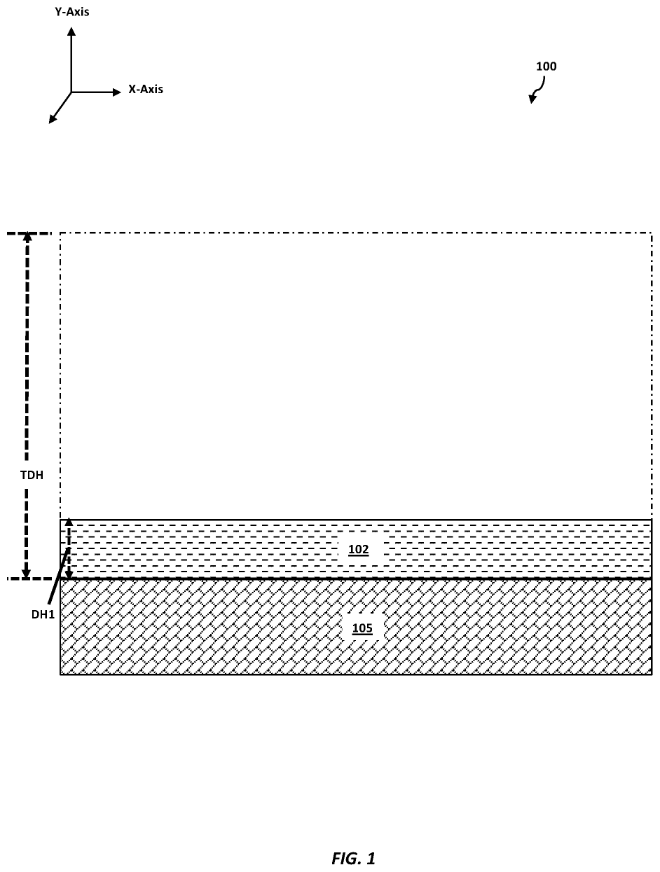

FIGS. 1-19 illustrate cross-sectional views of a structure and the respective processing steps for creating the structure, in accordance with an embodiment of the present disclosure. The cross-sectional view that is illustrated in each Figure is a cross-section that cuts through a plurality of adjacent lines, where the lines are in parallel to each other.

Specifically, FIG. 1 illustrates a cross-sectional view of an initial structure of a device 100 after a first dielectric layer 102 is formed on a base layer 105.

The first dielectric layer 102 is formed on the base layer 105 using various techniques, which may include, for example, PVD, CVD, ECD, MBE, ALD, spin coating, or other suitable techniques or combination of techniques. The first dielectric layer 102 may be selected from the group including, for example, organic polymer low-k dielectrics, organosilicate glass-based low-k dielectrics (e.g., SiCOH, SiCNOH), or any other suitable dielectric material with a low-k constant relative to silicon dioxide (SiO2).

According to one embodiment, the first dielectric layer 102 includes a first dielectric layer height DH1 extending along a Y-axis. The first dielectric layer height DH1 is associated with a thickness or vertical dimension of the first dielectric layer 102 formed on the base layer 105. As will be further detailed below, a final structure of device 100 includes a plurality of dielectric layers comprising a total dielectric layer height TDH extending parallel to the Y-axis. In one embodiment, the first dielectric layer height DH1 is less than 50% of the total dielectric layer height TDH of the plurality of dielectric layers. In one embodiment, the first dielectric layer height DH1 represents approximately 25% of the total dielectric layer height TDH of the plurality of dielectric layers. In other embodiments, the percentage of the total dielectric layer height TDH represented by the first dielectric layer height DH1 varies based on a total number of dielectric layers in the final structure. As an example, the first dielectric layer height DH1 may include a non-limiting thickness of approximately 5 nanometer (nm) to 25 nm, although thickness values below 5 nm and above 25 nm are also considered.

According to one embodiment, the base layer 105 includes any foundational layer that is configured to support the formation of interconnects or other IC components and layers. Base layer 105 is illustrated as a substrate for example purposes only and is not meant to be limiting. The substrate can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials may be used as the semiconductor material of the substrate. In some embodiments, the substrate may include both semiconductor materials and dielectric materials. The semiconductor substrate may also comprise an organic semiconductor or a layered semiconductor such as, for example, Si/SiGe, a silicon-on-insulator, or a SiGe-on-insulator. A portion or the entire semiconductor substrate may also be comprised of an amorphous, polycrystalline, or monocrystalline. The semiconductor substrate may be doped, undoped, or contain doped regions and undoped regions therein.

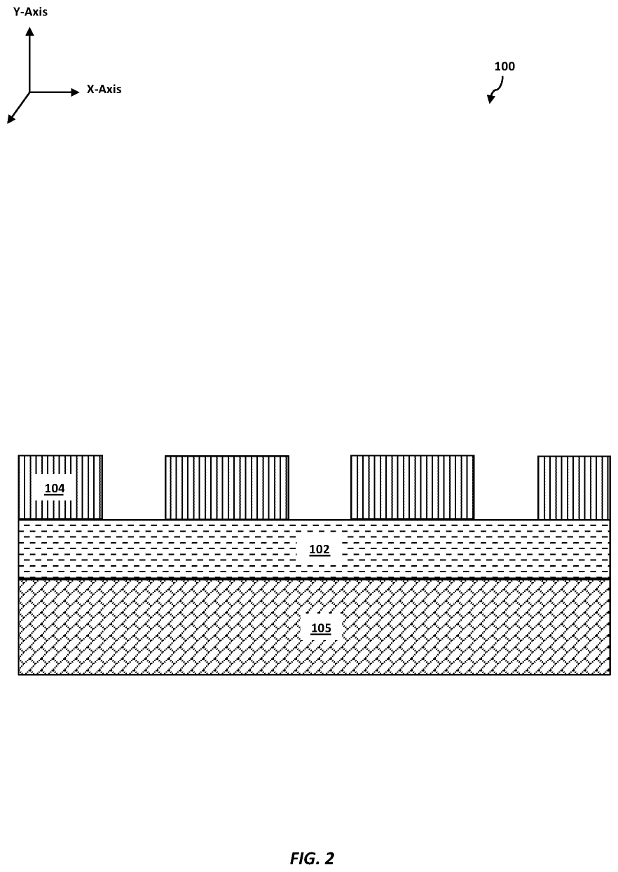

FIG. 2 illustrates a cross-sectional view of a partial structure of device 100 after a first hardmask layer 104 is patterned on a top surface (e.g., exposed surface) of the first dielectric layer 102.

Once the first hardmask layer 104 is formed on the top surface of the first dielectric layer 102, a photoresist layer (not shown) is applied to an exposed surface of the first hardmask layer 104 and patterned using lithography techniques to remove portions of the photoresist material. The pattern of the photoresist layer is associated with defining the locations and shapes of any trenches and vias that may be subsequently formed and filled with conductive material. Once the photoresist layer has been patterned, the pattern is transferred from the photoresist layer to the first hardmask layer 104 using an etching process. As illustrated in FIG. 2, the etching process selectively removes portions of the first hardmask layer 104 that does not include the photoresist material to form the patterned first hardmask layer 104.

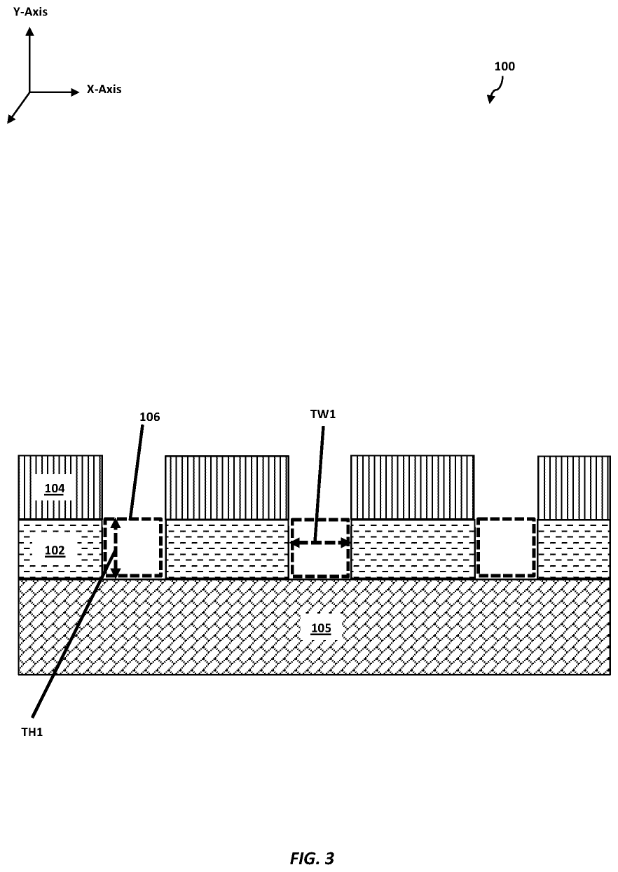

FIG. 3 illustrates a cross-sectional view of the partial structure of device 100 after the first dielectric layer 102 is selectively etched to create one or more trenches 106, as emphasized using the dashed-boxes 106 (hereinafter referred to as trench 106).

The patterned first hardmask layer 104 enables the selective etching of the underlying first dielectric layer 102, resulting in trenches 106 that are aligned with the patterned first hardmask layer 104. Each trench 106 includes a low aspect ratio, where the dimension of a width TW1 of the trench 106 (e.g., defined by patterned first hardmask layer 104) extending along the X-axis is similar to the dimension of a height TH1 of the trench 106 (e.g., defined by the first dielectric layer height DH1) extending along the Y-axis. The advantages associated with the low aspect ratio dimensions of trenches 106 will be detailed further below.

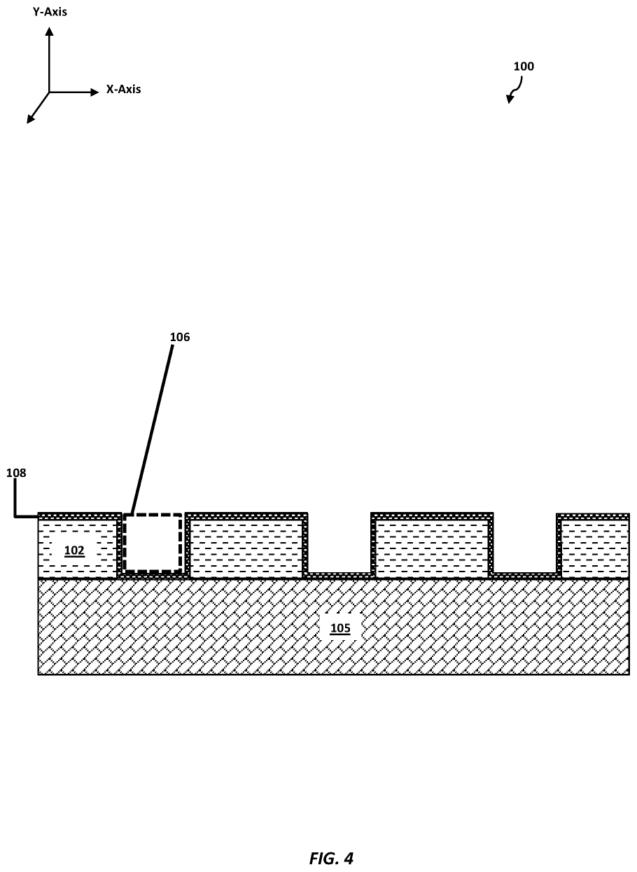

FIG. 4 illustrates a cross-sectional view of the partial structure of device 100 after the first hardmask layer 104 is removed and a first barrier layer 108 is deposited.

The first hardmask layer 104 is removed from the top surface of the first dielectric layer 102 using a selective etching process to expose the top surface of the first dielectric layer 102. A first barrier layer 108 is formed on the exposed top surface of the first dielectric layer 102 and along a boundary of each trench 106. The boundary of trench 106 includes the exposed sidewalls of the first dielectric layer 102 and the exposed top surface of the base layer 105.

The first barrier layer 108 is formed on the plurality of exposed surfaces using various techniques, which may include, for example, PVD, CVD, ECD, MBE, ALD, spin coating, or other suitable techniques or combination of techniques. The first barrier layer 108 is formed before depositing any conductive material (e.g., interconnect metal fill) in trenches 106 to prevent the diffusion or migration of materials between the conductive material in trenches 106 and the first dielectric layer 102, as well as between the conductive material in trenches 106 and the base layer 105.

Barrier materials for the first barrier layer 108 may be selected from the group including, for example, tantalum carbide (TaC), tantalum nitride (TaN), tungsten carbide (WC), or any other conductive material that may prevent diffusion/migration between the materials in trenches 106, first dielectric layer 102, or base layer 105. Barrier materials for the first barrier layer 108 is selected based on the ability of the barrier material to nucleate well on the first dielectric layer 102 (e.g., barrier material is compatible with low-k first dielectric layer 102 material).

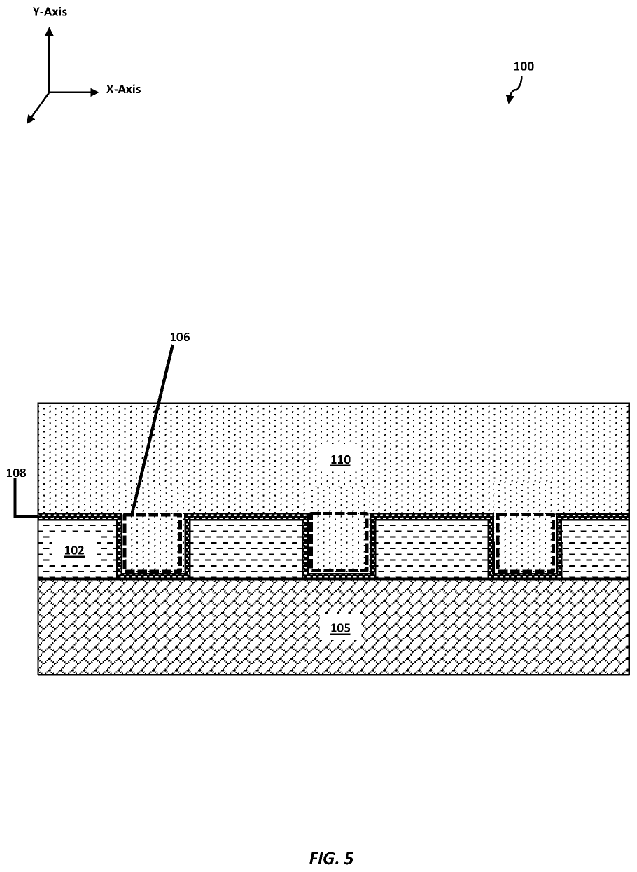

FIG. 5 illustrates a cross-sectional view of the partial structure of device 100 after a metallization process to form a first conductive material 110 on the exposed surfaces.

The first conductive material 110 is formed over the top surface of the first barrier layer 108 and the first dielectric layer 102 to fill the one or more trenches 106. The first conductive material 110 is formed using various techniques, which may include, for example, PVD, CVD, ECD, MBE, ALD, spin coating, or other suitable techniques or combination of techniques. The first conductive material 110 may be selected from the group including, for example, copper (Cu), molybdenum (Mo), ruthenium (Ru), tungsten (W), iridium (Ir), nickel (Ni), or any other suitable conductive material.

The low aspect ratio dimensions of trench 106 allow for the first conductive material 110 to fill the trench 106 with a low risk of incomplete filling or voids. Further, relative to the width TW1 of the trench 106, the shallow depth (e.g., height TH1) of the trench 106 provided by its low aspect ratio allow for the first conductive material 110 to fill the trench 106 with a low risk of the first conductive material 110 accumulating at the edges of the trench 106. The uniform filling of the first conductive material 110 also reduces the risk of line wiggling caused by variations in line width and height.

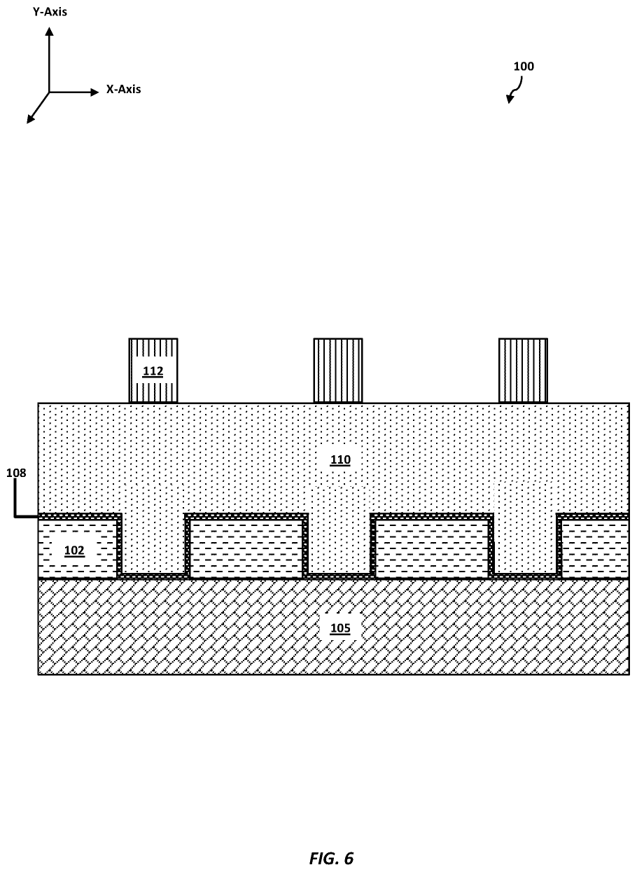

FIG. 6 illustrates a cross-sectional view of the partial structure of device 100 after a second hardmask layer 112 is patterned on a top surface (e.g., exposed surface) of the first conductive material 110.

Once the second hardmask layer 112 is formed on the top surface of the first conductive material 110, a photoresist layer (not shown) is applied to an exposed surface of the second hardmask layer 112 and patterned using lithography techniques to remove portions of the photoresist material. The pattern of the photoresist layer is associated with defining the locations and patterns of a subsequent etching process that may be applied to the first conductive material 110. Once the photoresist layer has been patterned, the pattern is transferred from the photoresist layer to the second hardmask layer 112 using an etching process. As illustrated in FIG. 6, the etching process selectively removes portions of the second hardmask layer 112 that does not include the photoresist material to form the patterned second hardmask layer 112.

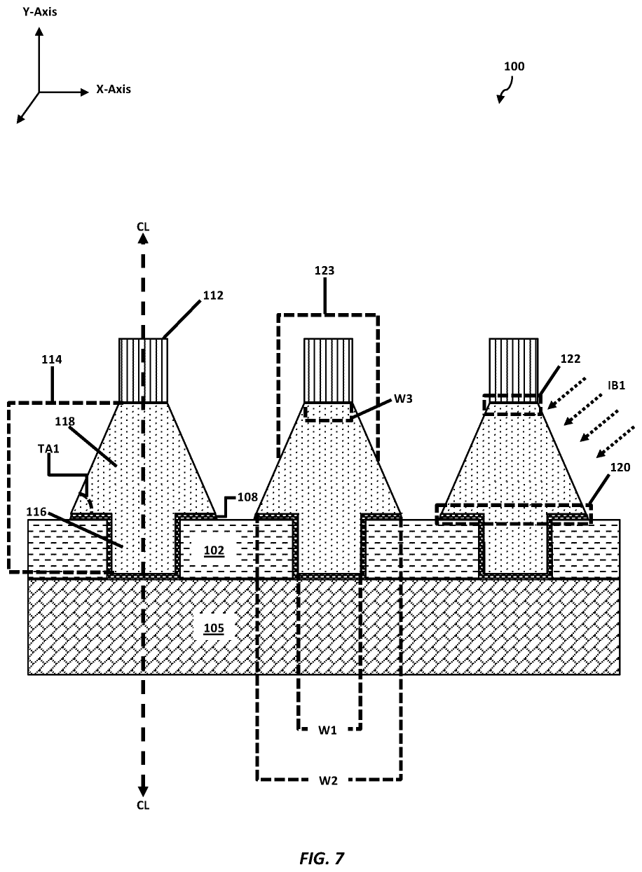

FIG. 7 illustrates a cross-sectional view of the partial structure of device 100 after the first conductive material 110 and the first barrier layer 108 is selectively etched.

The selective etching of the first conductive material 110 and the first barrier layer 108 forms one or more bottom interconnect sections 114, as emphasized by dashed-bracket 114 (hereinafter referred to as the bottom interconnect section 114). The bottom interconnect section 114 includes a first orientation extending along the Y-axis and comprises a first interconnect portion 116 and a second interconnect portion 118.

The first interconnect portion 116 of the bottom interconnect section 114 is comprised of a region of the first conductive material 110 formed in trench 106 (see FIG. 5). As such, the first interconnect portion 116 is located between first sections of the first dielectric layer 102. The first interconnect portion 116 includes a first substantially perpendicular profile including a first pair of vertical sidewalls that are parallel to the Y-axis and extend between the top surface of the first barrier layer 108 that is formed on the base layer 105 and the top surface of the first barrier layer 108 that is formed on the top surface of the first dielectric layer 102. The first interconnect portion 116 includes a first width W1 extending parallel to the X-axis between the first pair of vertical sidewalls of the first interconnect portion 116.

The second interconnect portion 118 of the bottom interconnect section 114 is formed by selectively etching the first conductive material 110 and the first barrier layer 108 to achieve a tapered metal etch of the first conductive material 110 and the first barrier layer 108. The selective etching process may be implemented using dry etching techniques (e.g., ion beam etching (IBE)), wet etching techniques, or other suitable etching techniques or a combination of etching techniques.

When selective etching is performed using IBE, the IBE process selectively removes regions of the first conductive material 110 and the first barrier layer 108 to form a first tapered profile of the second interconnect portion 118. The first tapered profile corresponds to an angle of incidence of first ion beams IB1 (represented using dashed-arrows labeled IB1) directed at the first conductive material 110 and the first barrier layer 108. The IBE process includes an etch depth that is set to the top surface of the first dielectric layer 102 such that the selective etching will stop at the top surface of the first dielectric layer 102.

The second interconnect portion 118 includes a first wider region 120, as emphasized by dashed-box 120, (hereinafter referred to as the first wider region 120), that is formed along the top surface of the first barrier layer 108. The second interconnect portion 118 is in direct contact with the first interconnect portion 116 and extends upwards from the first interconnect portion 116 such that the second interconnect portion 118 is connected to and located above the first interconnect portion 116. More specifically, the first wider region 120 of the second interconnect portion 118 extends along the top surface of the first barrier layer 108, perpendicularly from the first pair of vertical sidewalls of the first interconnect portion 116 on opposite sides of a center line CL (parallel to the Y-axis) defined by the bottom interconnect section 114. The first wider region 120 includes a second width W2 that extends parallel to the X-axis.

The second interconnect portion 118 also includes a first narrower region 122, as emphasized by dashed-box 122, (hereinafter referred to as the first narrower region 122), that is located above the first wider region 120 and formed along a bottom surface of the second hardmask layer 112. The first narrower region 122 is parallel to the first wider region 120 and includes a third width W3 that extends parallel to the X-axis.

The second width W2 of the first wider region 120 is greater than the third width W3 of the first narrower region 122. The first width W1 of the first interconnect portion 116 is less than the second width W2 of the first wider region 120 of the second interconnect portion 118. In one embodiment, the first width W1 of the first interconnect portion 116 and the third width W3 of the first narrower region 122 of the second interconnect portion 118 includes a same width. In at least one embodiment, the first width W1 of the first interconnect portion 116 and the third width W3 of the first narrower region 122 of the second interconnect portion 118 includes a different width such that the first width W1 may be greater than or less than the third width W3.

The second interconnect portion 118 further includes a first pair of tapered sidewalls 123, as emphasized by dashed-bracket 123 (hereinafter referred to as the first pair of tapered sidewalls 123). The first pair of tapered sidewalls 123 respectively connects each ends of the first wider region 120 and the first narrower region 122. More specifically, the first pair of tapered sidewalls 123 tapers up towards center line CL from the first wider region 120 of the second interconnect portion 118 to define the first narrower region 122 of the second interconnect portion 118. As a result of tapering up from the first wider region 120 to the first narrower region 122 that is above the first wider region 120, the first tapered profile of the second interconnect portion 118 forms an A-shaped profile.

The tapering of the first pair of tapered sidewalls 123 towards the center line CL forms a first taper angle TA1 between each of the first pair of tapered sidewalls 123 and the first wider region 120. TA1 may include an acute angle having a non-limiting exemplary range between 25 to 45 degrees.

Based on the above and as illustrated in FIG. 7, the bottom interconnect section 114 includes a first arrow-shaped profile, where the second interconnect portion 118 comprises a first arrowhead portion of the first arrow-shaped profile and the first interconnect portion 116 comprises a first shaft portion of the first arrow-shaped profile. The first arrow-shaped profile of the bottom interconnect section 114 is oriented perpendicular to the top surface of the base layer 105 and extends upwards along the Y-axis such that the first arrowhead portion points away from the top surface of the base layer 105.

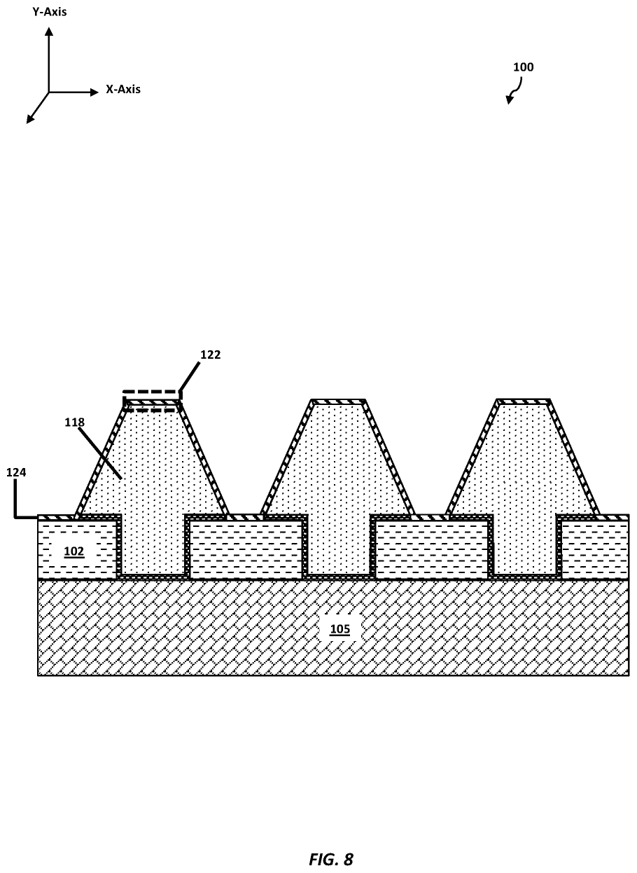

FIG. 8 illustrates a cross-sectional view of the partial structure of device 100 after the second hardmask layer 112 is removed and a second barrier layer 124 is formed.

The second hardmask layer 112 is be removed from a top surface of the first narrower region 122 of the second interconnect portion 118 using a selective etching process to expose the top surface of the first narrower region 122. Then, the second barrier layer 124 is formed on the exposed top surface of the first dielectric layer 102 and along exposed outer boundaries of the second interconnect portions 118 (including the exposed top surface of the first narrower region 122 of the second interconnect portion 118).

The second barrier layer 124 is formed on the plurality of exposed surfaces using various techniques, which may include, for example, PVD, CVD, ECD, MBE, ALD, spin coating, or other suitable techniques or combination of techniques. The second barrier layer 124 is formed before depositing materials in the regions above the exposed top surface of the first dielectric layer 102 and the regions surrounding the second interconnect portions 118. The second barrier layer 124 prevents the diffusion or migration of materials between the exposed top surface of the first dielectric layer 102 and the second interconnect portions 118 and between the second interconnect portions 118 and the regions surrounding the second interconnect portions 118.

Barrier materials for the second barrier layer 124 may be selected from the group including, for example, TaC, TaN, WC, or any other conductive material that may prevent diffusion/migration between the surrounding regions. Barrier materials for the second barrier layer 124 are selected based on the ability of the barrier material to nucleate well on the outer boundaries of the second interconnect portions 118 (e.g., barrier material is compatible with the first conductive material 110 used to form the second interconnect portions 118).

In one embodiment, the barrier material of the first barrier layer 108 is different from the barrier material of the second barrier layer 124 because the first barrier layer 108 has to nucleate on a low-k dielectric material (e.g., first dielectric layer 102), whereas the second barrier layer 124 has to nucleate on the first conductive material 110 used to form the second interconnect portions 118 (e.g., a metal). In one embodiment, the first barrier layer 108 includes TaC and the second barrier layer 124 includes TaN. In other embodiments, the first barrier layer 108 includes any conductive material that nucleates well on the first dielectric layer 102 and the second barrier layer 124 includes any conductive material that nucleates well on the first conductive material 110.

In another embodiment, the first barrier layer 108 and the second barrier layer 124 employs different barrier materials because some barrier materials may be better suited for a specific deposition technique and/or a specific deposition surface geometry (e.g., barrier deposition along a trench with perpendicular sidewalls versus barrier deposition along a tapered sidewall surface). However, in at least one embodiment, the first barrier layer 108 and the second barrier layer 124 includes the same barrier material.

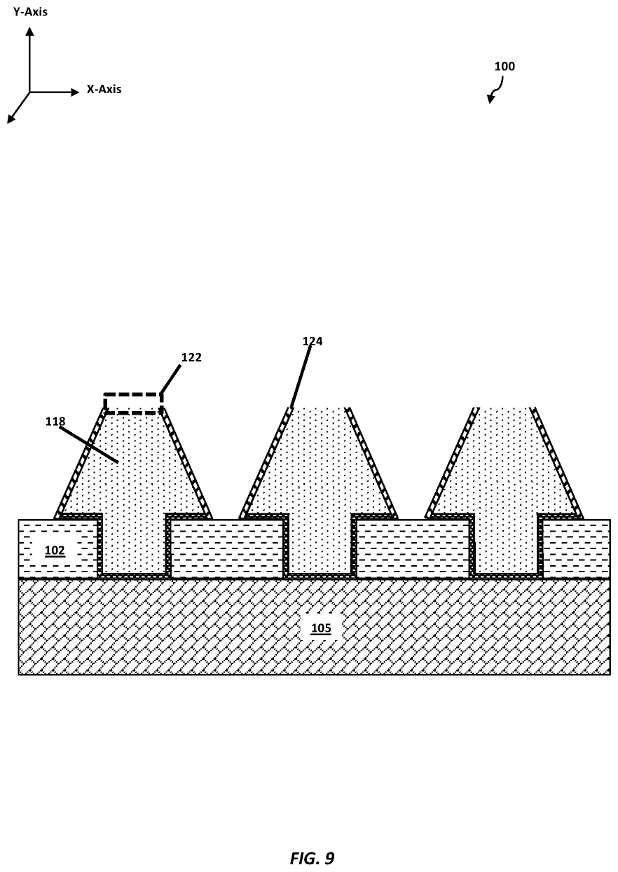

FIG. 9 illustrates a cross-sectional view of the partial structure of device 100 after regions of the second barrier layer 124 are selectively removed.

Regions of the second barrier layer 124 that were formed on the horizontal surfaces (e.g., surfaces parallel to the X-axis) of device 100 are selectively removed. The horizontal surfaces of the device 100 that are impacted by the selective removal of the second barrier layer 124 includes the top surface of the first dielectric layer 102 as well as the top surface of the first narrower region 122 of the second interconnect portion 118. The second barrier layer 124 is removed from the horizontal surfaces using, for example, reactive ion etching (RIE), IBE, or any other directional etching process or combination of etching processes.

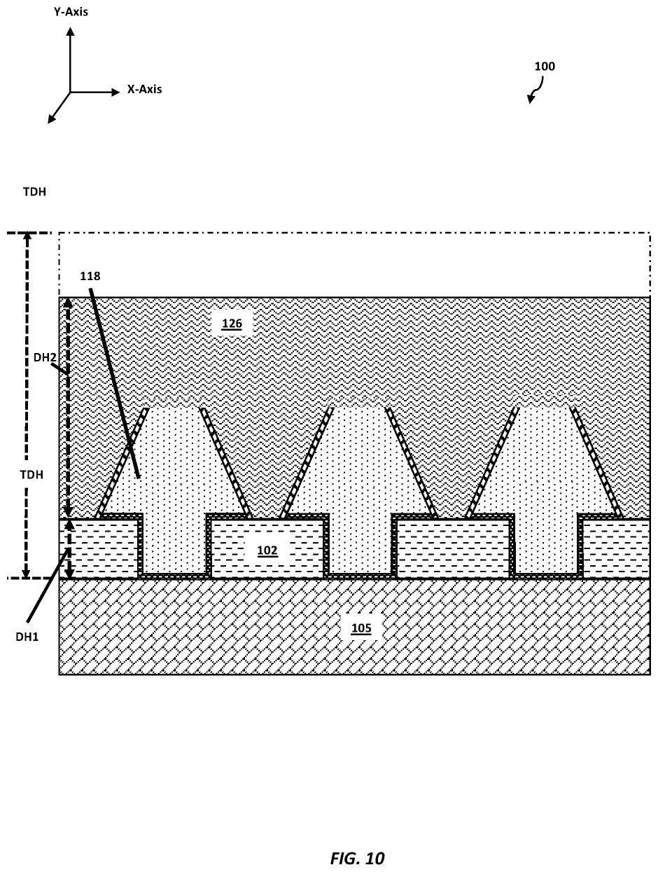

FIG. 10 illustrates a cross-sectional view of the partial structure of device 100 after a second dielectric layer 126 is formed.

The second dielectric layer 126 is formed over the exposed top surface of the first dielectric layer 102 and over the regions surrounding the second interconnect portion 118, using various techniques, which may include, for example, PVD, CVD, ECD, MBE, ALD, spin coating, or other suitable techniques or combination of techniques. As such, the second interconnect portion 118 is located between second sections of the second dielectric layer 126. The second dielectric layer 126 may be selected from the group including, for example, organic polymer low-k dielectrics, organosilicate glass-based low-k dielectrics (e.g., SiCOH, SiCNOH), or any other suitable low-k dielectric material. In one embodiment, the low-k dielectric material of the first dielectric layer 102 is different from the low-k dielectric material of the second dielectric layer 126. In at least one embodiment, the low-k dielectric material of the first dielectric layer 102 is the same as the low-k dielectric material of the second dielectric layer 126.

The second dielectric layer 126 includes a second dielectric layer height DH2 extending parallel to the Y-axis. The second dielectric layer height DH2 is associated with a thickness or vertical dimension of the second dielectric layer 126 extending from the exposed top surface of the first dielectric layer 102.

The second dielectric layer height DH2 is greater than the first dielectric layer height DH1. In one embodiment, the second dielectric layer height DH2 is approximately double the first dielectric layer height DH1 and represents approximately 50% of the total dielectric layer height TDH of the plurality of dielectric layers. In other embodiments, the percentage of the total dielectric layer height TDH represented by the second dielectric layer height DH2 varies based on a total number of dielectric layers in the final structure. As an example, the second dielectric layer height DH2 includes a non-limiting thickness of approximately 10 nm to 50 nm, although thickness values below 10 nm and above 50 nm are also considered.

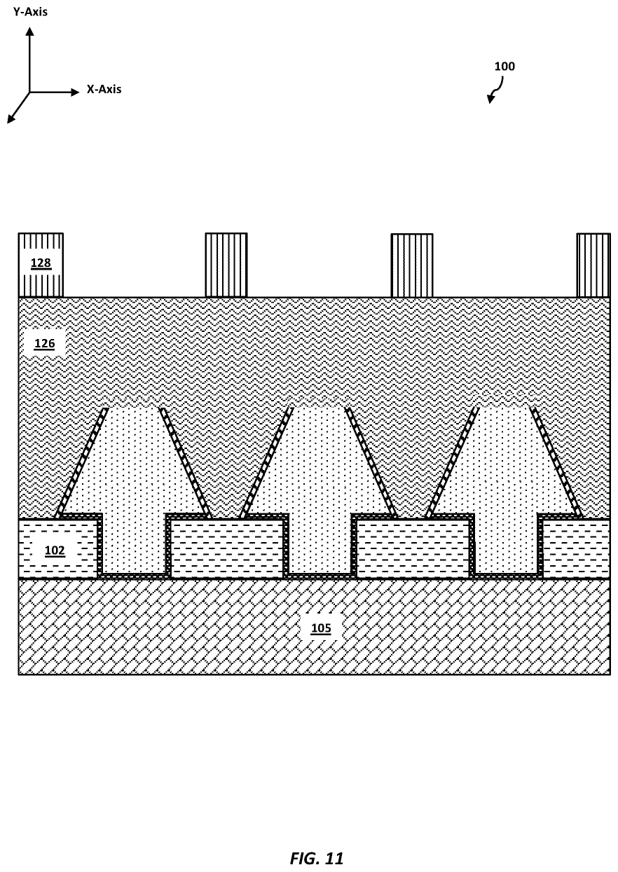

FIG. 11 illustrates a cross-sectional view of the partial structure of device 100 after a third hardmask layer 128 is patterned on a top surface (e.g., exposed surface) of the second dielectric layer 126.

Once the third hardmask layer 128 is deposited on the top surface of the second dielectric layer 126, a photoresist layer (not shown) is applied to an exposed surface of the third hardmask layer 128 and patterned using lithography techniques to remove portions of the photoresist material. The pattern of the photoresist layer may be associated with defining the locations and shapes of any trenches and vias that may be subsequently formed and filled with conductive material. Once the photoresist layer has been patterned, the pattern is transferred from the photoresist layer to the third hardmask layer 128 using an etching process. As illustrated in FIG. 11, the etching process may selectively remove portions of the third hardmask layer 128 that do not include the photoresist material to form the patterned third hardmask layer 128.

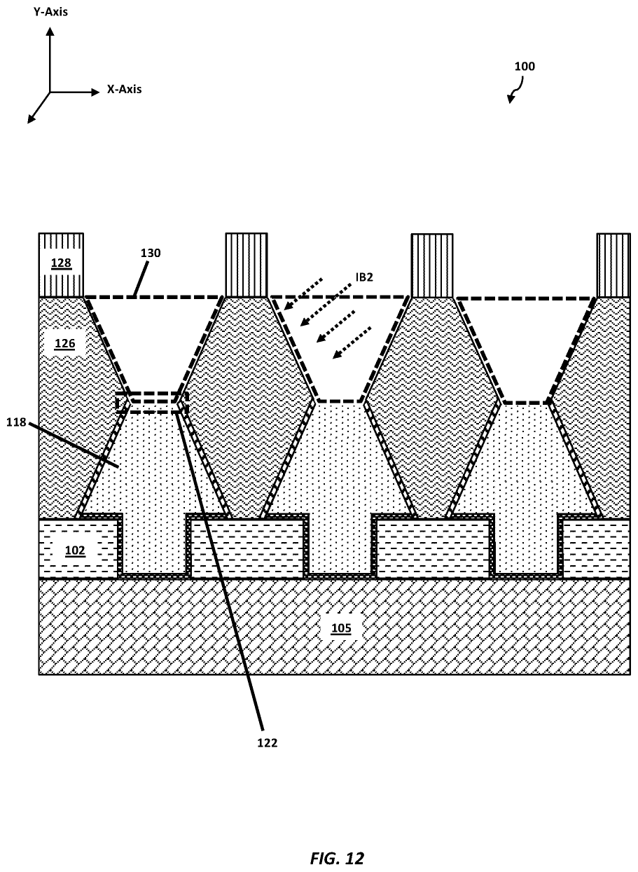

FIG. 12 illustrates a cross-sectional view of the partial structure of device 100 after the second dielectric layer 126 is selectively etched.

The selective etching of the second dielectric layer 126 forms one or more tapered trenches 130 therein, as shown using the dashed-shape labeled 130. The selective etching process may be implemented using dry etching techniques (e.g., IBE), wet etching techniques, or other suitable etching techniques or a combination of etching techniques.

When selective etching is performed using IBE, the IBE process may selectively remove the second dielectric layer 126 to form the tapered profile of the tapered trenches 130 based on the angle of incidence of second ion beams IB2 (represented using dashed-arrows labeled IB2) directed at the second dielectric layer 126. The IBE process includes an etch depth that is set to the top surface of the first narrower region 122 of the second interconnect portion 118 such that the selective etching will stop at the top surface of the first narrower region 122. Each tapered trench 130 includes low aspect ratio dimensions which provides advantages that will be detailed further below.

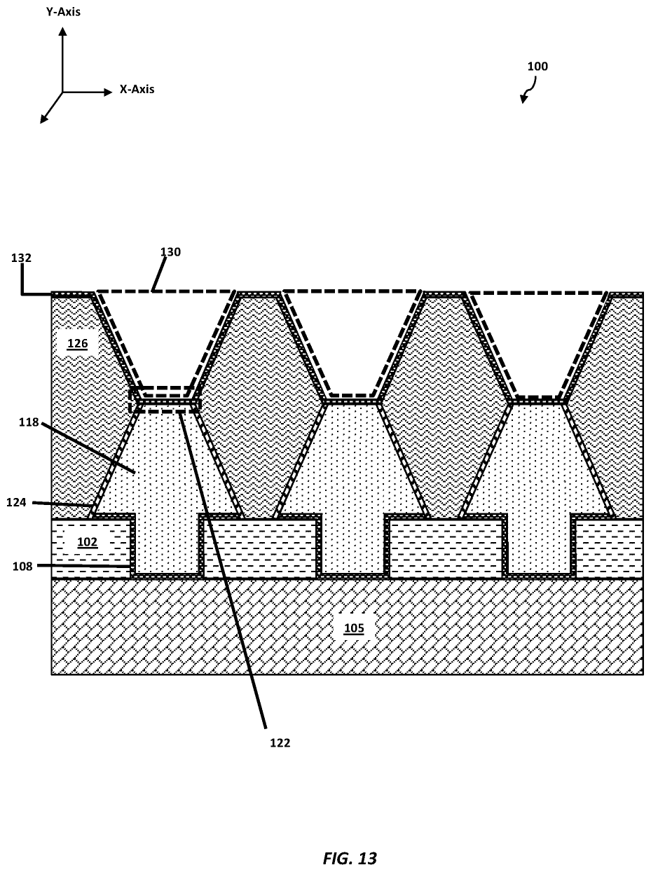

FIG. 13 illustrates a cross-sectional view of the partial structure of device 100 after the third hardmask layer 128 is removed and a third barrier layer 132 is deposited.

The third hardmask layer 128 is removed from the top surface of the second dielectric layer 126 using a selective etching process to expose the top surface of the second dielectric layer 126. Then, the third barrier layer 132 is formed on the exposed top surface of the second dielectric layer 126 and along a boundary of each tapered trench 130. The boundary of tapered trench 130 includes the exposed tapered sidewalls of the second dielectric layer 126 and the exposed top surface of the first narrower region 122 of the second interconnect portion 118. The third barrier layer 132 is formed on the plurality of exposed surfaces using various techniques, which may include, for example, PVD, CVD, ECD, MBE, ALD, spin coating, or other suitable techniques or combination of techniques. The third barrier layer 132 is formed before depositing any conductive material (e.g., interconnect metal fill) in tapered trenches 130 to prevent the diffusion or migration of materials between the conductive material in tapered trenches 130 and the second dielectric layer 126.

Barrier materials for the third barrier layer 132 may be selected from the group including, for example, TaC, TaN, WC, or any other conductive material that may prevent diffusion/migration between the conductive material in tapered trenches 130 and the second dielectric layer 126. Barrier materials for the third barrier layer 132 is selected based on the ability of the barrier material to nucleate well on the second dielectric layer 126 (e.g., barrier material is compatible with low-k second dielectric layer 126 material).

In one embodiment, the barrier material of the third barrier layer 132 is different from the barrier material of the second barrier layer 124 because the third barrier layer 132 has to nucleate on a low-k dielectric material (e.g., second dielectric layer 126), whereas the second barrier layer 124 has to nucleate on a metal (e.g., second interconnect portion 118 formed using first conductive material 110). In one embodiment, the third barrier layer 132 includes TaC and the second barrier layer 124 may include TaN. In other embodiments, the third barrier layer 132 includes any conductive material that nucleates well on the second dielectric layer 126 and the second barrier layer 124 includes any conductive material that nucleates well on the first conductive material 110.

In one embodiment, the barrier material of the third barrier layer 132 is the same as the barrier material of the first barrier layer 108 (e.g., both using TaC). However, in one embodiment, the first barrier layer 108 and the third barrier layer 132 employs different barrier materials because some barrier materials may be better suited for a specific deposition technique and/or a specific deposition surface geometry (e.g., barrier deposition along a trench with perpendicular sidewalls versus barrier deposition along a tapered sidewall surface). Further, in at least one embodiment, the first barrier layer 108, the second barrier layer 124, and the third barrier layer 132 includes the same barrier materials.

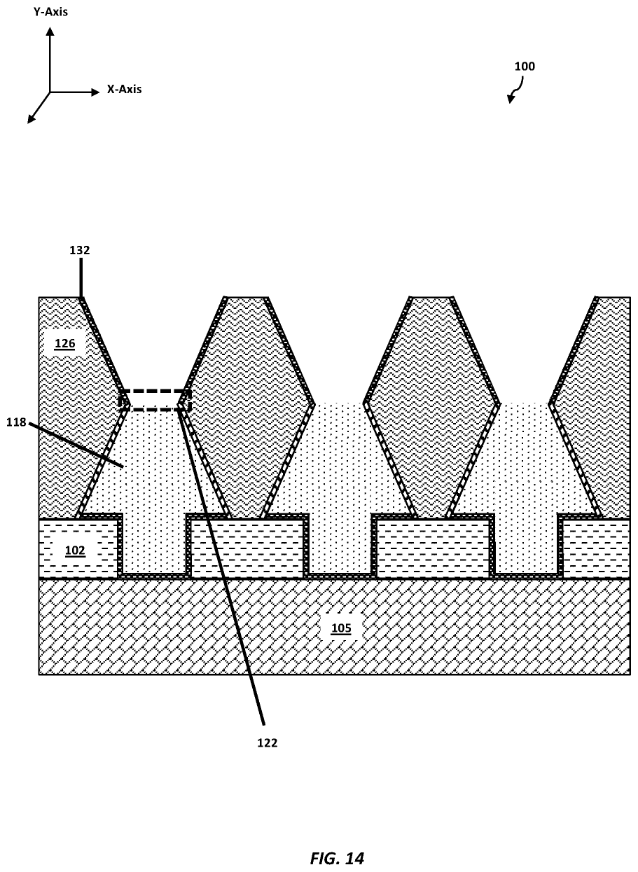

FIG. 14 illustrates a cross-sectional view of the partial structure of device 100 after regions of the third barrier layer 132 are selectively removed.

Regions of the third barrier layer 132 that were formed on the horizontal surfaces (e.g., surfaces parallel to the X-axis) of device 100 are selectively removed. The horizontal surfaces of the device 100 that are impacted by the selective removal of the third barrier layer 132 includes the top surface of the second dielectric layer 128 and the top surface of the first narrower region 122 of the second interconnect portion 118. The third barrier layer 132 is removed from the horizontal surfaces using, for example, RIE, IBE, or any other directional etching process or combination of etching processes.

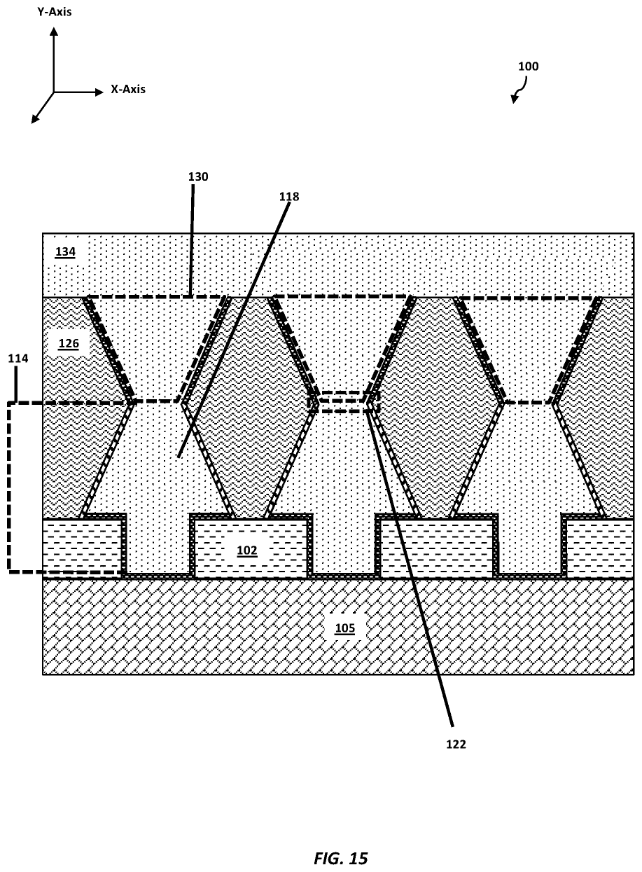

FIG. 15 illustrates a cross-sectional view of the partial structure of device 100 after a second conductive material 134 is formed.

The second conductive material 134 is formed over the top surface of the third barrier layer 132 and the second dielectric layer 126 to fill the one or more tapered trenches 130. Once the second conductive material 134 is filled into the tapered trenches 130, the second conductive material 134 is in direct contact with the first conductive material 110 (see FIG. 6) fill at the top surface of the first narrower region 122 of the second interconnect portion 118 (of the bottom interconnect section 114) to form a continuous material fill between the second conductive material 134 and the first conductive material 110 (of the bottom interconnect section 114).

The second conductive material 134 is formed using various techniques, which may include, for example, PVD, CVD, ECD, MBE, ALD, spin coating, or other suitable techniques or combination of techniques. In one embodiment, the second conductive material 134 may be selected from the group including, for example, Cu, Mo, Ru, W, Ir, Ni, or any other suitable conductive material. In one embodiment, the first conductive material 110 (of the bottom interconnect section 114) and the second conductive material 134 includes different conductive materials. However, in at least one embodiment, the first conductive material 110 and the second conductive material 134 includes the same conductive material.

As described previously with reference to FIG. 12, tapered trench 130 may include low aspect ratio dimensions. The low aspect ratio dimensions of trench 130 allow for the second conductive material 134 to fill the trench 130 with a low risk of incomplete filling or voids. Further, relative to a width of the trench 130 (not shown), the shallow depth (e.g., parallel to the Y-axis) of the trench 130 provided by its low aspect ratio dimensions allow for the second conductive material 134 to fill the trench 130 with a low risk of the second conductive material 134 accumulating non-uniformly on the tapered sidewalls. The uniform filling of the second conductive material 134 also reduces the risk of line wiggling caused by variations in line width and height.

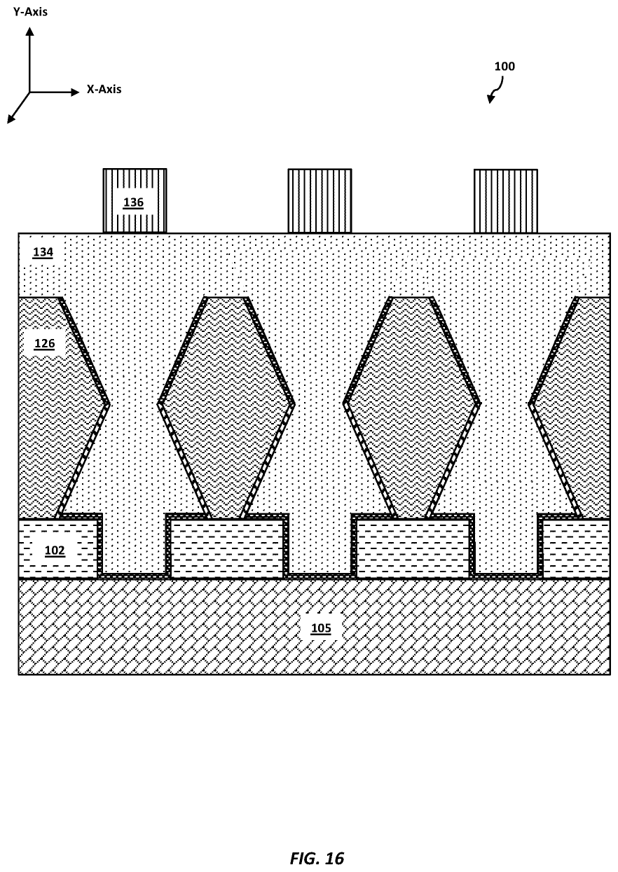

FIG. 16 illustrates a cross-sectional view of the partial structure of device 100 after a fourth hardmask layer 136 is patterned on a top surface (e.g., exposed surface) of the second conductive material 134.

Once the fourth hardmask layer 136 is formed on the top surface of the second conductive material 134, a photoresist layer (not shown) is applied to an exposed surface of the fourth hardmask layer 136 and patterned using lithography techniques to remove portions of the photoresist material. The pattern of the photoresist layer is associated with defining the locations and patterns of a subsequent etching process that may be applied to the second conductive material 134. Once the photoresist layer has been patterned, the pattern is transferred from the photoresist layer to the fourth hardmask layer 136 using an etching process. As illustrated in FIG. 16, the etching process selectively removes portions of the fourth hardmask layer 136 that does not include the photoresist material to form the patterned fourth hardmask layer 136.

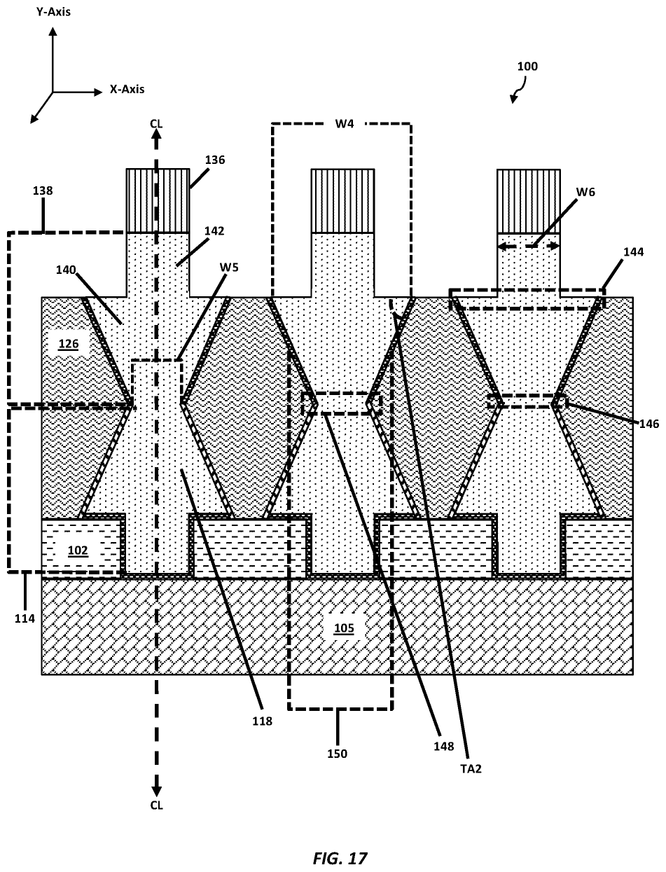

FIG. 17 illustrates a cross-sectional view of the partial structure of device 100 after the second conductive material 134 is selectively etched.

The selective etching of the second conductive material 134 forms one or more top interconnect sections 138, as emphasized by dashed-bracket 138, (hereinafter referred to as the top interconnect section 138). The top interconnect section 138 comprises a third interconnect portion 140 and a fourth interconnect portion 142.

The third interconnect portion 140 of the top interconnect section 138 is comprised of a region of the second conductive material 134 deposited in the tapered trench 130 (see FIG. 15). As such, the third interconnect portion 140 is located between the second sections of the second dielectric layer 126 and includes a second tapered profile that corresponds to a tapered profile of the tapered trench 130 (see FIG. 15). The top interconnect section 138 includes a second orientation along the Y-axis, that is a vertical reflection of the first orientation of the bottom interconnect section 114. Thus, the second orientation of the top interconnect section 138 opposes the first orientation of the bottom interconnect section 114.

The third interconnect portion 140 includes a second wider region 144, as emphasized by dashed-box 144, (hereinafter referred to as the second wider region 144). The second wider region 144 is formed at a trench opening portion of the tapered trench 130 (see FIG. 15) such that a top surface of the second wider region 144 and the top surface of the second dielectric layer 126 are substantially coplanar relative to a horizontal plane (e.g., parallel to X-axis). The second wider region 144 extends parallel to the X-axis on opposite sides of the center line CL defined by the bottom interconnect section 114 (see FIG. 7) to define a fourth width W4.

The third interconnect portion 140 also includes a second narrower region 146, as emphasized by dashed-box 146, (hereinafter referred to as the second narrower region 146). The second narrower region 146 is located below the second wider region 144 (along the Y-axis) and is formed along the top surface of the first narrower region 122 of the second interconnect portion 118 (see FIG. 7). More specifically, once the second conductive material 134 is filled into the tapered trenches 130, the second narrower region 146 is in direct contact (e.g., overlaps) with the first narrower region 122 of the second interconnect portion 118 to form an intersection 148, as emphasized using the dashed-box, (hereinafter referred to as the intersection 148), between the top interconnect section 138 and the bottom interconnect section 114. The second conductive material 134 of the top interconnect section 138 and the first conductive material 110 of the bottom interconnect section 114 joins at intersection 148 to form a continuous metal fill or structure.

The second narrower region 146 is parallel to the second wider region 144 and includes a fifth width W5 that extends parallel to the X-axis. The fourth width W4 of the second wider region 144 is greater than the fifth width W5 of the second narrower region 146. The fifth width W5 of the second narrower region 146 is equal to the third width W3 of the first narrower region 122 (see FIG. 7), resulting in the intersection 148 formed between the second narrower region 146 and the first narrower region 122. Since the fifth width W5 of the second narrower region 146 is equal to the third width W3 of the first narrower region 122, the fifth width W5 of the second narrower region 146 is also less than the second width W2 of the first wider region 120 of the second interconnect portion 118 (see FIG. 7). Similarly, the third width W3 of the first narrower region 122 of the second interconnect portion 118 is also less than the fourth width W4 of the second wider region 144 of the third interconnect portion 140.

The third interconnect portion 140 further includes a second pair of tapered sidewalls 150, as emphasized by the dashed-bracket 150 (hereinafter referred to as the second pair of tapered sidewalls 150). The second pair of tapered sidewalls 150 respectively connects each end of the second wider region 144 and the second narrower region 146. More specifically, the second pair of tapered sidewalls 150 extends from opposite ends of the second wider region 144, tapers down toward the center line CL, and connects to opposite ends of the second narrower region 146. The second pair of tapered sidewalls 150 tapers down from the second wider region 144 of the third interconnect portion 140 towards the center line CL to define the second narrower region 146 of the third interconnect portion 140. As a result of tapering from the second wider region 144 to the second narrower region 146 that is below the second wider region 144, the second tapered profile of the third interconnect portion 140 includes a V-shaped profile. The V-shaped profile (e.g., second tapered profile) of the third interconnect portion 140 intersects with the A-shaped profile (e.g., first tapered profile) of the second interconnect portion 118 at intersection 148, as illustrated in FIG. 17.

The tapering of the second pair of tapered sidewalls 150 towards the center line CL forms a second taper angle TA2 between each of the second pair of tapered sidewalls 150 and the second wider region 144. The second taper angle TA2 includes an acute angle having a non-limiting exemplary range between 25 to 45 degrees. In one embodiment, the second taper angle TA2 and the first taper angle TA1 (see FIG. 7) includes the same angle. In another embodiment, the second taper angle TA2 and the first taper angle TA1 (see FIG. 7) includes different angles (e.g., one taper angle may be greater than the other taper angle).

As described previously, the selective etching of the second conductive material 134 forms the fourth interconnect portion 142 of the top interconnect section 138. The selective etching process may be implemented using dry etching techniques (e.g., IBE), wet etching techniques, or other suitable etching techniques or a combination of etching techniques.

When selective etching is performed using IBE, the IBE process selectively removes regions of the second conductive material 134 to form the fourth interconnect portion 142 as including a second substantially perpendicular profile, with second vertical sidewalls that are parallel to the Y-axis and extend out of and upwards away from the second wider region 144 of the third interconnect portion 140 (e.g., along the Y-axis). As such, the fourth interconnect portion 142 is connected to and located above the third interconnect portion 140 along the Y-axis. The IBE process includes an etch depth that is set to the top surface of the second dielectric layer 126 such that the selective etching of the second conductive material 134 will stop at the top surface of the second dielectric layer 126. Once the fourth interconnect portion 142 is formed, the top surface of the second wider region 144 and the top surface of the second dielectric layer 126 are substantially coplanar relative to a horizontal plane (e.g., parallel to X-axis).

The fourth interconnect portion 142, formed by the selective etching process, includes a sixth width W6 extending between the second vertical walls thereof, parallel to the X-axis. The second wider region 144 of the third interconnect region 144 extends perpendicularly from the second vertical sidewalls of the fourth interconnect portion 142 on opposite sides of a center line CL (parallel to the Y-axis) such that the fourth width W4 of the second wider region 144 is greater than the sixth width W6 of the fourth interconnect portion 142. In one embodiment, the sixth width W6 of the fourth interconnect portion 142 and the fifth width W5 of the second narrower region 146 includes a same width. In at least one embodiment, the sixth width W6 of the fourth interconnect portion 142 and the fifth width W5 of the second narrower region 146 includes a different width such that the sixth width W6 is greater than or less than the fifth width W5.

Based on the above and as illustrated in FIG. 17, the top interconnect section 138 includes a second arrow-shaped profile, where the third interconnect portion 140 comprises a second arrowhead portion of the second arrow-shaped profile and the fourth interconnect portion 142 comprises a second shaft portion of the second arrow-shaped profile. The second arrow-shaped profile of the top interconnect section 138 is oriented perpendicular to the top surface of the second dielectric layer 126 and extends downwards along the Y-axis such that the second arrowhead portion points towards the top surface of the base layer 105 (e.g., opposing the orientation of the first arrow-shaped profile of the bottom interconnect section 114). The first arrowhead portion of the first arrow-shaped profile and the second arrowhead portion of the second arrow-shaped profile forms a hyperboloid line profile along the Y-axis.

According to one embodiment, the top interconnect section 138 (e.g., forming the second arrow-shaped profile) and the bottom interconnect section 114 (e.g., forming the first arrow-shaped profile) includes opposing orientations along the Y-axis (e.g., vertical reflection). In such embodiments, the orientation of the top interconnect section 138 mirrors the orientation of the bottom interconnect section 114 relative to a horizontal axis (e.g., parallel to X-axis) defined by the intersection 148 (e.g., top and bottom interconnect sections have opposite orientations). In such embodiments, the top interconnect section 138 and the bottom interconnect section 114 are congruent (e.g., include the same dimensions).

In another embodiment, the top interconnect section 138 and the bottom interconnect section 114 may include mirror orientations without symmetry. In such embodiments, the orientation of the top interconnect section 138 mirrors the orientation of the bottom interconnect section 114 relative to the horizontal axis defined by the intersection 148, but the top interconnect section 138 and the bottom interconnect section 114 do not include the same dimensions.

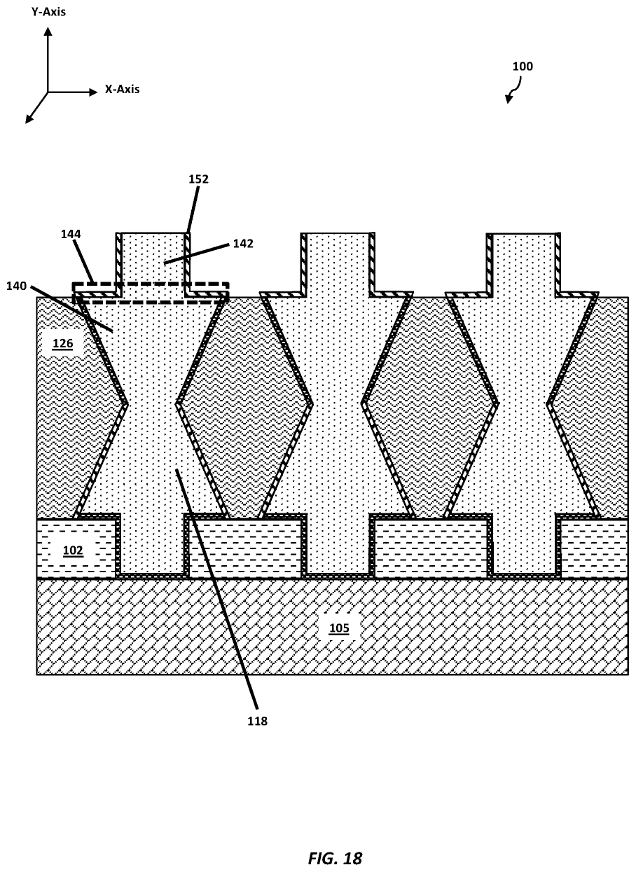

FIG. 18 illustrates a cross-sectional view of the partial structure of device 100 after a fourth barrier layer 152 is formed and the fourth hardmask layer 136 is removed.

The fourth barrier layer 152 is formed before removing the fourth hardmask layer 136 to prevent the fourth barrier layer 152 from forming on the top surface of the fourth interconnect portion 142. In one embodiment, the fourth barrier layer 152 is formed using ALD or another suitable selective deposition technique such that the fourth barrier layer 152 selectively nucleates and forms on the top surface of the second wider region 144 of the third interconnect portion 140 and the second vertical sidewalls of the fourth interconnect portion 142. However, in another embodiment, the fourth barrier layer 152 is formed using various techniques, which may include, for example, PVD, CVD, ECD, MBE, spin coating, or other suitable techniques or combination of techniques.

The fourth barrier layer 152 is formed before depositing materials in the regions above the exposed top surface of the second dielectric layer 128 and the regions surrounding the second wider region 144 of the third interconnect portion 140 and the second vertical sidewalls of the fourth interconnect portion 142 to prevent the diffusion or migration of materials between the surrounding regions (e.g., exposed top surface of the second dielectric layer 128 and the second wider region 144 of the third interconnect portion 140 and the second vertical sidewalls of the fourth interconnect portion 142).

Barrier materials for the fourth barrier layer 152 may be selected from the group including, for example, TaC, TaN, WC, or any other conductive material that may prevent diffusion/migration between the surrounding regions. Barrier materials for the fourth barrier layer 152 is selected based on the ability of the barrier material to selectively nucleate well on the second conductive material 134 (see FIG. 16) of the third interconnect portion 140 and the fourth interconnect portion 142 (e.g., barrier material is compatible with conductive material).

In one embodiment, the barrier material of the fourth barrier layer 152 is different from the barrier materials of the first barrier layer 108, the second barrier layer 124, and the third barrier layer 132 because the fourth barrier layer 152 needs to selectively nucleate on a metal (e.g., second conductive material 134 of the third interconnect portion 140 and the second vertical sidewalls of the fourth interconnect portion 142). In contrast, the first barrier layer 108 and the third barrier layer 132 are formed on respective low-k dielectric materials and the second barrier layer 124 is formed on both, a low-k dielectric material and a metal, using a non-selective formation technique, before being etched back from the low-k dielectric material. In one embodiment, the fourth barrier layer 152 includes WC, whereas the first barrier layer 108 and the third barrier layer 132 both include TaC, and the second barrier layer 124 includes TaN. However, in at least one embodiment, the first barrier layer 108, the second barrier layer 124, the third barrier layer 132, and the fourth barrier layer 152 includes the same barrier material.

Once the fourth barrier layer 152 is formed, the fourth hardmask layer 136 is removed from the top surface of the fourth interconnect portion 142 using a selective etching process.

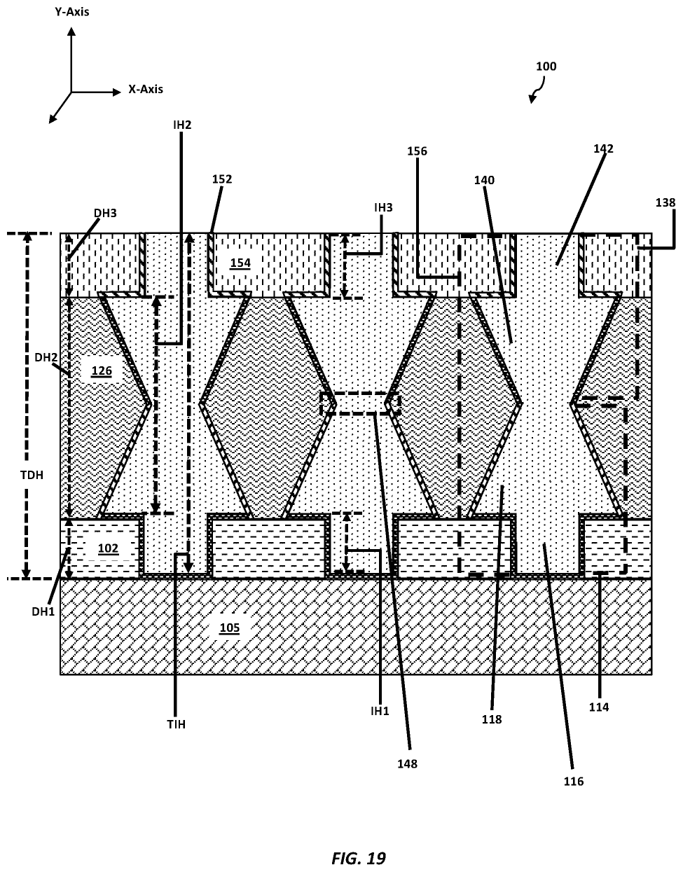

FIG. 19 illustrates a cross-sectional view of a final structure of device 100 after a third dielectric layer 154 is formed.

The third dielectric layer 154 is formed on the top surface of the second dielectric layer 126 and the fourth barrier layer 152 using various techniques, which may include, for example, PVD, CVD, ECD, MBE, ALD, spin coating, or other suitable techniques or combination of techniques. As such, the fourth interconnect portion 142 is located between third sections of the third dielectric layer 154. The third dielectric layer 154 may be selected from the group including, for example, organic polymer low-k dielectrics, organosilicate glass-based low-k dielectrics (e.g., SiCOH, SiCNOH), or any other suitable low-k dielectric material.

In one embodiment, different low-k dielectric materials are implemented for each of the first dielectric layer 102, the second dielectric layer 126, and the third dielectric layer 154. However, in at least one embodiment, the same low-k dielectric material is implemented for each of the first dielectric layer 102, the second dielectric layer 126, and the third dielectric layer 154. In another embodiment, the same low-k dielectric material is implemented for two of the three dielectric layers (e.g., same low-k dielectric material for first dielectric layer 102 and third dielectric layer 154; different low-k dielectric material for second dielectric layer 126).

The third dielectric layer 154 includes a third dielectric layer height DH3 extending parallel to the Y-axis. The third dielectric layer height DH3 is associated with a thickness or vertical dimension of the third dielectric layer 154 extending from the exposed top surface of the second dielectric layer 126. In one embodiment, the third dielectric layer height DH3 is less than the second dielectric layer height DH2, and approximately equal to the first dielectric layer height DH1. In one embodiment, the third dielectric layer height DH3 is approximately 25% of the total dielectric layer height TDH of the plurality of dielectric layers (e.g., the first dielectric layer 102, the second dielectric layer 126, and the third dielectric layer 154), similar to the first dielectric layer height DH1. In other embodiments, the percentage of the total dielectric layer height TDH represented by the third dielectric layer height DH3 varies based on a total number of dielectric layers in the final structure. As an example, the third dielectric layer height DH3 includes a non-limiting thickness of approximately 5 nm to 25 nm, although thickness values below 5 nm and above 25 nm are also considered.

As illustrated in FIG. 19, the final structure of device 100 includes an interconnect system (e.g., semiconductor device) comprising a plurality of interconnects 156, as emphasized by dashed-bracket 156 (hereinafter referred to as interconnect 156). Each interconnect 156 includes the bottom interconnect section 114 and the top interconnect section 138, joined together at intersection 148.

The bottom interconnect section 114 includes the first interconnect portion 116 and the second interconnect portion 118. The top interconnect section 138 includes the third interconnect portion 140 and the fourth interconnect portion 142. The first interconnect portion 116 of the bottom interconnect section 114 includes a first interconnect height IH1 that is approximately equal to the first dielectric layer height DH1. The second interconnect portion 118 of the bottom interconnect section 114 and the third interconnect portion 140 of the top interconnect section 138 includes a combined second interconnect height IH2 that is approximately equal to the second dielectric layer height DH2. The fourth interconnect portion 142 of the top interconnect section 138 includes a third interconnect height IH3 that is approximately equal to the third dielectric layer height DH3. The first interconnect height IH1, the second interconnect height IH2, and the third interconnect height IH3 comprises a total interconnect height TIH that is approximately equal to the total dielectric layer height TDH. Thus, since each of the plurality of interconnects 156 includes the same first interconnect height IH1, the same second interconnect height IH2, and the same third interconnect height IH3 comprising a same total interconnect height TIH, the plurality of interconnects 156 includes a uniform total interconnect height TIH.

As previously described, each of the first, second, third, and fourth interconnect portions 116, 118, 140, 142 includes a low aspect ratio and are formed sequentially to build the final structure of interconnect 156. Thus, while the final structure of interconnect 156 includes a high aspect ratio, the sequential stages of forming low aspect ratio interconnect portions to build the final structure of interconnect 156 reduces the typical risks of line wiggling and metal gapfill errors associated with building high aspect ratio features in one stage.

According to one embodiment, each of the plurality of interconnects 156 includes a uniform line profile having the following features: the first interconnect portion 116 forming a lower interconnect section located between the first sections of the first dielectric layer 102, the second interconnect portion 118 and the third interconnect portion 140 forming opposing middle interconnect sections located between second sections of the second dielectric layer 126, and the fourth interconnect portion 142 forming an upper interconnect section located between third sections of the third dielectric layer 154. The two opposing middle interconnect sections (e.g., second interconnect portion 118 and third interconnect portion 140) located between sections of the second dielectric layer 126 comprises a hyperboloid line profile, where the first tapered profile of the second interconnect portion 118 includes an opposing orientation relative the second tapered profile of the third interconnect portion 140 relative to intersection 148. The first interconnect portion 116 and the fourth interconnect portion 142 also forms opposing interconnect sections as each of the first interconnect portion 116 and the fourth interconnect portion 142 extends from opposite ends of the interconnect 156 along the Y-axis.

The hyperboloid line profile includes respective opposing portions with locally widened CDs, where locally widened CDs promote lower line resistance in interconnect 156. The first wider region 120 (see FIG. 7) of the second interconnect portion 118 comprises the first locally widened CD and the second wider region 144 (see FIG. 17) of the third interconnect portion 140 comprises the second locally widened CD of the hyperboloid line profile. The second locally widened CD (e.g., second wider region 144) includes an opposing orientation relative to the first locally widened CD (e.g., first wider region 120). The uniform line profile across the plurality of interconnects 156 is enabled by the sequential forming of low aspect ratio interconnect sections (e.g., the first, second, third, and fourth interconnect portions 116, 118, 140, 142) to build the hyperboloid line profile of interconnect 156.

The number of interconnects, interconnect sections, interconnect portions, dielectric layers, hardmask layers, and barrier layers described above are not intended to be limiting, and it may be appreciated that in various embodiments of the present disclosure, the number of interconnects, interconnect sections, interconnect portions, dielectric layers, hardmask layers, and metal barrier layers may vary.

It may be appreciated that FIGS. 1-19 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
an interconnect including:
a bottom interconnect section having a first orientation along a Y-axis; and
a top interconnect section coupled to the bottom interconnect section and having a second orientation along to the Y-axis, wherein the second orientation of the top interconnect section is a vertical reflection of the first orientation of the bottom interconnect section.

2. The semiconductor device of claim 1, wherein the bottom interconnect section comprises:
a first interconnect portion; and
a second interconnect portion located above the first interconnect portion, the second interconnect portion including:
a first wider region;
a first narrower region located above the first wider region; and
a first pair of tapered sidewalls that connects the first wider region and the first narrower region.

3. The semiconductor device of claim 2, wherein the top interconnect section comprises:
a third interconnect portion including:
a second narrower region;
a second wider region located above the second narrower region; and
a second pair of tapered sidewalls that connects the second wider region and the second narrower region; and
a fourth interconnect portion located above the second wider region of the third interconnect portion.

4. The semiconductor device of claim 3, wherein the first pair of tapered sidewalls tapers up from the first wider region of the second interconnect portion towards a center line defined by the bottom interconnect section to define the first narrower region of the second interconnect portion, and wherein the second pair of tapered sidewalls tapers down from the second wider region of the third interconnect portion towards the center line to define the second narrower region of the third interconnect portion.

5. The semiconductor device of claim 3, wherein the first pair of tapered sidewalls of the second interconnect portion and the second pair of tapered sidewalls of the third interconnect portion includes opposing orientations relative to each other along the Y-axis.

6. The semiconductor device of claim 3, further comprises:
an intersection formed by the second narrower region of the third interconnect portion and the first narrower region of the second interconnect portion, wherein the intersection joins the top interconnect section and the bottom interconnect section to form a continuous structure.

7. The semiconductor device of claim 3, wherein the first interconnect portion extends a first width parallel to an X-axis, and wherein the first wider region of the second interconnect portion extends perpendicularly from the first interconnect portion on opposite sides of a center line defined by the bottom interconnect section to define a second width parallel to the X-axis, wherein the first width is less than the second width.

8. The semiconductor device of claim 7, wherein the second width of the first wider region tapers up to the first narrower region of the second interconnect portion, wherein the first narrower region extends a third width parallel to the X-axis, and wherein the second width of the first wider region is greater than the third width of the first narrower region.

9. The semiconductor device of claim 8, wherein the second wider region of the third interconnect portion extends a fourth width parallel to the X-axis and tapers down to the second narrower region of the third interconnect portion, wherein the second narrower region extends a fifth width parallel to the X-axis, and wherein the fourth width is greater than the fifth width.

10. The semiconductor device of claim 9, wherein the fourth width of the second wider region of the third interconnect portion and the second width of the first wider region of the second interconnect portion include a same width parallel to the X-axis.

11. A semiconductor device, comprising:
an interconnect including:
a first interconnect portion extending along a Y-axis;
a second interconnect portion extending upwards from the first interconnect portion along the Y-axis and including a first tapered profile;
a third interconnect portion extending upwards from the second interconnect portion along the Y-axis and including a second tapered profile having an opposing orientation relative to the first tapered profile of the second interconnect portion; and
a fourth interconnect portion extending upwards from the third interconnect portion along the Y-axis.

12. The semiconductor device of claim 11, wherein the first tapered profile of the second interconnect portion and the second tapered profile of the third interconnect portion forms a hyperboloid line profile along the Y-axis.

13. The semiconductor device of claim 12, wherein the hyperboloid line profile includes a first locally widened critical dimension (CD) defined by a first wider region of the second interconnect portion and a second locally widened CD defined by a second wider region of the third interconnect portion, wherein the first locally widened CD includes the opposing orientation relative to the second locally widened CD.

14. The semiconductor device of claim 12, wherein the first interconnect portion is located between first sections of a first dielectric layer, the second interconnect portion and the third interconnect portion are located between second sections of a second dielectric layer, and the fourth interconnect portion is located between third sections of a third dielectric layer.

15. The semiconductor device of claim 14, wherein the first dielectric layer locating the first interconnect portion and the third dielectric layer locating the third interconnect portion comprises different dielectric materials, and wherein the second dielectric layer comprises a same dielectric material for the second interconnect portion and the third interconnect portion.

16. A semiconductor device, comprising:
a first interconnect including:
a bottom interconnect section including a first arrow-shaped profile extending along a Y-axis; and
a top interconnect section including a second arrow-shaped profile extending along the Y-axis, wherein the second arrow-shaped profile includes an opposite orientation relative to the first arrow-shaped profile.

17. The semiconductor device of claim 16, wherein the bottom interconnect section includes a first interconnect portion and a second interconnect portion, wherein the second interconnect portion comprises a first arrowhead portion of the first arrow-shaped profile and the first interconnect portion comprises a first shaft portion of the first arrow-shaped profile.

18. The semiconductor device of claim 17, wherein the top interconnect section includes a third interconnect portion and a fourth interconnect portion, wherein the third interconnect portion comprises a second arrowhead portion of the second arrow-shaped profile and the fourth interconnect portion comprises a second shaft portion of the second arrow-shaped profile.

19. The semiconductor device of claim 18, wherein the first arrowhead portion of the first arrow-shaped profile and the second arrowhead portion of the second arrow-shaped profile forms a hyperboloid line profile along the Y-axis.

20. The semiconductor device of claim 16, further comprising a second interconnect, wherein the second interconnect and the first interconnect includes a uniform total interconnect height and a uniform line profile.
